(19) United States
(12) Patent Application Publication
(10) Pub. No.: US 2026/0235705 A1
(43) Pub. Date: Aug. 13, 2026

(54) 1-D LATTIC OPTICAL TRAP VIA MAGNETO-OPTICAL ROTATION IN A BI-REFRINGENT MEDIUM

(71) Applicant: Institute of Applied Technology, Fatima College of Health and Science, Abu Dhabi (AE)

(72) Inventors: Nadia Boutabba, Abu Dhabi (AE); Ammara Qazi, Village Sikanderpur (PK); Hazrat Ali, Kokarai Village - SWAT District - KPK (PK)

(73) Assignee: Institute of Applied Technology, Fatima College of Health and Science, Abu Dhabi (AE)

(21) Appl. No.: 19/052,228

(22) Filed: Feb. 12, 2025

(51) Int. Cl. G01R 33/032; G01N 21/19

(52) U.S. Cl. CPC G01R 33/032; G01N 21/19

(57) ABSTRACT

A method, includes manipulating a left and right circularly polarized light, wherein left and right susceptibilities are fully controlled. The method includes controlling light transmission based on controlling the left and right susceptibilities. The method includes inducing an isotropy or anisotropy effect, wherein the isotropy or anisotropy effect is observable in a transmission or absorption spectra. The method includes manipulating a phase and magnetic field, wherein the manipulating the phase and magnetic field results in a honey comb behavior. The method includes determining a magneto-optical rotation (MOR) in a one-dimensional (1D) lattice via a four-level atomic system with bi-refringence.

### BACKGROUND

Recent advances in light-matter interaction enabled the manipulation and control of atoms, molecules and nano-sized particles. One particular area focuses on manipulating and efficiently controlling energetic states of an atom is the use coherent optical control of light via the magneto-optical rotation (MOR). This concept is based on the Faraday's effect where the polarization of light passing through a material and rotating enables the magnetic moments of atoms to interact with the electromagnetic fields. The magnetic field causes birefringence or dichroism in the medium for longitudinal fields (circular birefringence). In contrast, this is known as the Voigt effect for transverse fields.

In atomic systems, one technique for producing the MOR effect is the use of control laser beams able to manipulate the energetic states and hence the optical properties of a multilevel atom. In such systems, a strong control laser applied to one transition causes birefringence or dichroism in a probe laser on a second transition, similar to the phenomenon of electromagnetically induced transparency (EIT), wherein the control laser modifies the probe's absorption properties. The Coherent control of magneto-optic rotation was widely studied theoretically and experimentally in a variety of fields. For example, it has been observed high magneto-optical rotation of the polarization of light in an ensemble of Rubidium Vapor Rb87 and detected a large rotation angle of about 390 mrad for a medium with a short length of about (20 mm).

Along with these applications, the MOR can be effectively used in artificial micro-nano structures, magneto-optical sensors based on optical fibres, optical pump magnetometers, superconducting quantum interferometers among others. However, there is presently nothing that provides for magneto optical rotation in a 1-D optical lattice by controlling the transmission/absorption spectra while filtering the light.

### BRIEF DESCRIPTION OF DRAWINGS

FIGS. 1A and 1B are schematic diagrams of example systems;

FIGS. 2A 2B, and 2C, 2D, 2E, and 2F are diagrams of example graphs;

FIGS. 3A, 3B, and 3C are diagrams of example graphs;

FIGS. 4A, 4B, and 4C are diagrams of example graphs;

FIGS. 5A, 5B, and 5C are diagrams of example graphs;

FIGS. 6A, 6B, 6C, 6D, 6E, and 6F are diagrams of example graphs;

FIG. 7 is a diagram of a network environment;

FIG. 8 is a diagram of an example computing device;

FIG. 9 is a diagram of an example schematic trap; and

FIG. 10 is a diagram of an example graph.

### DETAILED DESCRIPTION OF PREFERRED EMBODIMENTS

The following detailed description refers to the accompanying drawings. The same reference numbers in different drawings may identify the same or similar elements.

Systems, devices, and/or methods described herein may allow for determining the Magneto-Optical Rotation (MOR) effect within a one-dimensional optical lattice with birefringence. In embodiments, a four-level atomic system is considered and described by two double-degenerated ground states driven by left and right circularly polarized optical light (LCL/RCL) and controlled via two strong lasers. In embodiments, the systems, devices, and/or methods described herein control the MOR and shape the transmission/absorption spectra in the 1D (one-dimensional) lattice. In embodiments, the external magnetic field affects the rotation of the plane of polarization of light passing through the medium, leading to a distinct change in the MOR that is attributed to an induced anisotropic effect.

In embodiments, the systems, methods, and/or devices used to control the MOR may be a type of optical tweezer that can be used to move and manipulate small particles using a beam of light. In embodiments, the optical tweezer can generate an optical trap by applying a standing wave to the system which has two components, left and right circularly polarized light. Accordingly, these two components can be used to generate the MOR. By manipulating the phase and the magnetic field, light filtering occurs through transmission/blockage pattern that mimic the honey comb behavior. In embodiments, by using a magnetic optical trap (MOT) device, two waves are generated and the phase difference between the two waves is manipulated.

Thus, the system, methods, and/or devices described herein provide a type of atomic control. By using the MOT, a magnetic field can influence a specific optical transition of the atom. By selecting the phase difference, and the magnetic detuning along with other parameters, atom's susceptibility can be controlled which in turn affects its ability to transmit or block light.

Furthermore, the control field strongly manipulates the dipole moment alignment in the intermediate transition which leads to a clockwise MOR reaching −13rd (“rd” refers to radians). In embodiments, the 1D optical lattice exhibits a centralized anisotropy around x=0, or an isotropic behavior (far from the center). Moreover, through precise manipulation of the phase and magnetic field strength of external fields, selective transmission or absorption peaks of light is achieved. This results in a honeycomb-like behavior of the LCL/RCL, effectively blocking or transmitting light. The systems, methods, and/or devices described herein can be used to engineer the 1D lattice to exhibit either isotropic or anisotropic behavior, allowing for selective transmission or absorption of light and tailored filtering based on polarization.

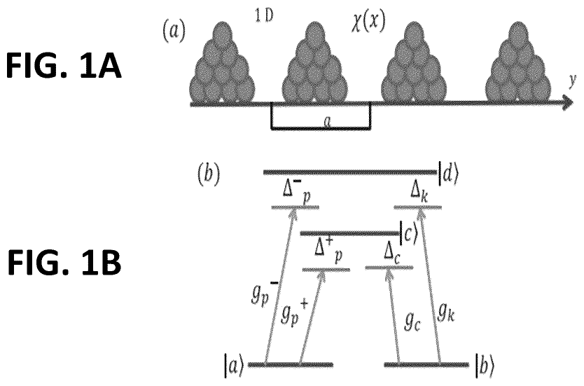

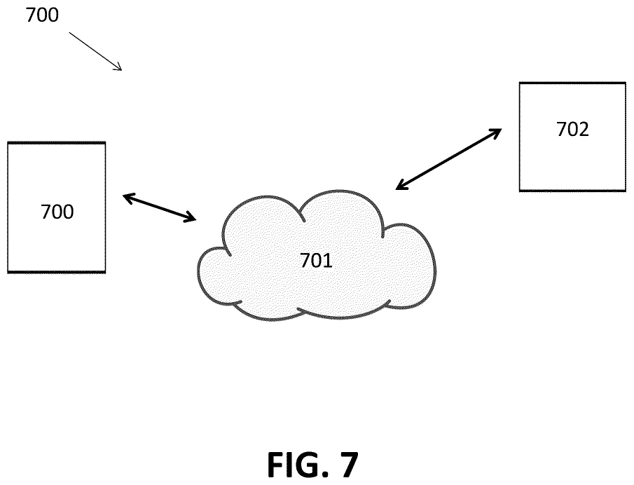

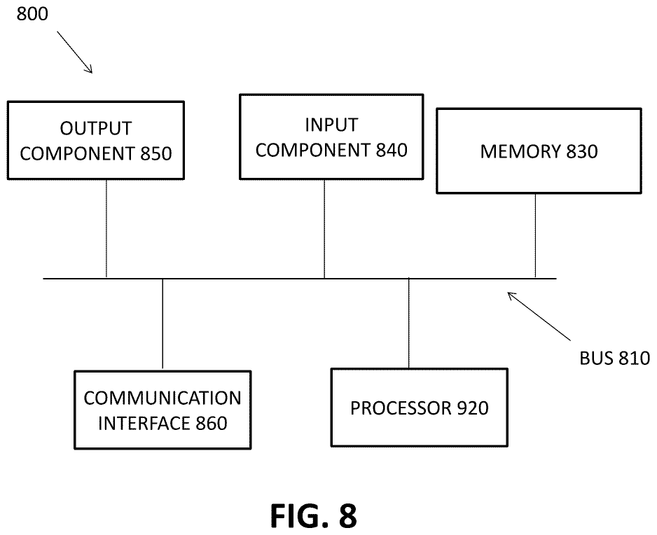

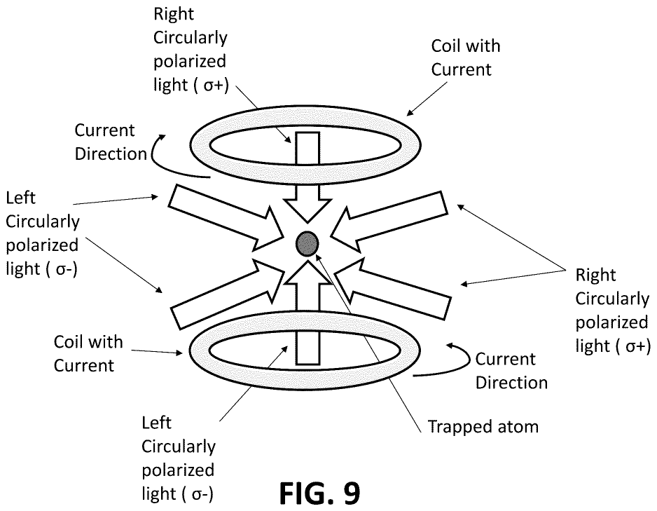

FIG. 9 describes an example schematic design for a trapping set up to trap an atom using a magnetic optical trap (MOT) device. In embodiments, the MOT acts, through the phase difference with specific values, to make the yellow trapped atom act as a quantum switch, blocking/filtering the light. As shown in FIG. 9, the schematic design describes a magnetic field, a current, and three beams of left circularly polarized lights and three beams of right circularly polarized light. In embodiments, the current refers to the current flowing through coils that generate the magnetic field gradient necessary to trap atoms within the MOT. In embodiments, changing the angle between the magnetic and electric component of the wave is used to trap the atom. In embodiments, the processes described in FIGS. 1-6 and 10 (by using the computing devices described in FIGS. 7 and 8) can be used to select the phase difference, and the magnetic detuning along with other parameters, and an atom's susceptibility can be controlled which in turn affects the atom's ability to transmit or block light

Accordingly, the systems, methods, and/or devices described herein determine the magneto-optical rotation (MOR) in a one-dimensional (1D) lattice via a four-level atomic system with bi-refringence. By manipulating the left and right circularly polarized light, the left and right susceptibilities in the medium are fully controlled, which in their turn enables the control of the light transmission. Thus, a high “MOR” is determined that reaches −13 rd and induces isotropy/anisotropy effect which can be observed in the transmission/absorption spectra. By manipulating the phase and the magnetic field, light filtering occurs through transmission/blockage pattern that mimic the honey comb behavior. The ability of modifying the transmission/absorption properties to filter the light is useful in applications such as single-photon switching, quantum memory, or quantum logic gates. Furthermore, applications such as nonlinear frequency conversion, optical switching, or generation of entangled photon pairs for quantum information processing may also occur based on the systems, methods, and/or devices described herein.

FIG. 1A describes a schematic diagram of one-dimensional optical lattice with atoms distributed on a Gaussian profile along the x-axis where a is the periodicity. The schematics of the configuration of the energy eigen levels of the double lambda EIT atoms are shown in FIG. 1B.

In embodiments, the model is based on a four level quantum system described in FIGS. 1A and 1B. This system describes an atom with two double-degenerate ground states, denoted by |1,m=+ [symbol] and |2,m=−1 [symbol] , and related to two upper transitions |3,m=0 [symbol] and |4,m=0 [symbol] . Such atomic configuration can be experimentally realized by an atomic vapor of 87Rb in the D2 lines. In embodiments, all is scaled to γ=10⁷, and γ_{ca}=γ_{da}=γ, γ_{ba}=0.5γ, gₖ is the control field between states |b [symbol] and |d [symbol] , g_{c} is the field between states |b [symbol] and |c [symbol] (described as y-dependent and modulated), gₚ is the probe field. The considered magnetic field (\vec{B}=Bz\hat{ }) is applied in the z-direction.

In embodiments, the energy splitting ratio is giving by ΔE=mₛgₛμ_{B}B/ℏ. In embodiments, the probe field \vec{E}=xEpe^{i(kpz-ωpt)}+c.c. is taken as linearly polarized and parallel to the magnetic field. Moreover, the right and left circularly polarized light is due to the respective Rabi frequencies gₚ+ and gₚ⁻. In embodiments, these two respective fields drive the transitions |a [symbol] ↔|c [symbol] and |d [symbol] ↔|a [symbol] . gₖ=μ₂₄·ε\hat{ }ℏEₖ where g₊=g₋=Ep/√2 and |μ₃₁|=|μ₄₁|. The splitting of Zeeman energy levels occurs in |c [symbol] and |d [symbol] and can be obtained by h⁻ΔE=mₛgₛμ_{B}B where μ_{B}(gₛ) is the Bohr's magneton (Lande's factor), and mₛ=±1 is the quantum number (magnetic) of the respective sub-levels of excited states. Furthermore, the density of rubidium atoms, in the one dimensional (1 D) optical lattice, is distributed in the Gaussian form as shown in FIGS. 1A and 1B.

In embodiments, the Hamiltonian of the system is given by equations (1) as:

$$H = - ℏ [ {g}_{p}^{-} {e}^{- i ( Δ p + Δ B ) t} \vert d 〉 〈 a \vert + {g}_{p}^{+} {e}^{- i ( Δ p - Δ B ) t} \vert c 〉 〈 a \vert + {g}_{c} {e}^{- i ( Δ c - Δ B ) t} \vert c 〉 〈 b \vert + {g}_{k} {e}^{- i ( Δ k - Δ B ) t} \vert d 〉 〈 b \vert + cc$$

while the density matrix equations for the four-level atom is written in equation (2) as:

$$ρ = {\sum }_{k , l} {ρ}_{kl} {e}^{ι ( {ω}_{k} - {ω}_{t} )} \vert k 〉 〈 l \vert \qquad ( 2 )$$

In embodiments, k,l denote the levels 1, 4 and ωk, l are the corresponding frequencies. In terms of the basis set of the bare atom |1 [symbol] , |2 [symbol] ,|3 [symbol] , |4 [symbol] , equation (3) and (4) are as follows:

$${ψ}_{k}^{†} {ψ}_{l} = \vert k 〉 〈 l \vert and ρ = {\sum }_{k , l = 1}^{n} {ρ}_{k l} \vert k 〉 〈 l \vert \qquad ( 3 )$$

ψ^{†}, ψₗ Raising and lower operator.

$$\frac{d ρ}{d t} = - \frac{ι}{ℏ} [ H , ρ ] \qquad ( 4 )$$

By replacing the Hamiltonian (in equation (1)) and the density matrix (equation (2)) in (equation (4)) the time evolution of the density operator can be determined and which is described by the Liouville Von Neumann equations. In embodiments, the off-diagonal elements are given by:

$${\dot{ρ}}_{c a} = ( ιΔ p - ιΔ B - {γ}_{c a} ) {ρ}_{c a} + ι {g}_{p}^{{}_{+}} ( {ρ}_{a a} - {ρ}_{c c} ) + ι {g}_{c} {ρ}_{ba} - ι {g}_{p}^{{}_{-}} {ρ}_{c d} \\ {\dot{ρ}}_{b a} = [ ( ιΔ p - ι Δ c ) - γ ba ] {ρ}_{b a} + ι {g}_{c} {{ρ}_{ca}}_{{-}^{}} ι {g}_{p}^{{}_{+}} {ρ}_{bc} - ι {g}_{p}^{{}_{-}} {ρ}_{b d} \\ {\dot{ρ}}_{d a} = ( ιΔ p + ιΔ B - {γ}_{d a} ) {ρ}_{d a} + ι {g}_{p}^{{}_{-}} ( {ρ}_{a a} - {ρ}_{d d} ) + ι {g}_{k} {ρ}_{ca} - ι {g}_{p}^{{}_{+}} {ρ}_{d c}$$

In embodiments, the off-diagonal elements of the density matrix describe the coherence in the system. The solutions read:

$${ρ}_{c a} = \frac{ι \cdot gc \cdot {g}_{k} {e}^{- ι ϕ}}{A B {C}_{1} + A {g}_{k}^{2} + {C}_{1} {g}_{c}^{2}} - \frac{ι {e}^{- ιϕ} ( B {C}_{1} + {g}_{k}^{2} )}{A B {C}_{1} + A {g}_{k}^{2} + {C}_{1} {g}_{c}^{2}} {ρ}_{d a} = \frac{ι \cdot gc \cdot {g}_{k} {e}^{- ι ϕ}}{A B {C}_{1} + A {g}_{k}^{2} + {C}_{1} {g}_{c}^{2}} - \frac{ι {e}^{- ι ϕ} ( A B + {g}_{c}^{2} )}{A B {C}_{1} + A {g}_{k}^{2} + {C}_{1} {g}_{c}^{2}} \qquad ( 8 )$$

$$where$$

$$A = - {γ}_{31} - i Δ B + i Δ p \qquad ( 8 )$$

$$B = - {γ}_{21} - i Δ c + i Δ p \qquad ( 9 )$$

$$C 1 = - {γ}_{41} + i Δ B + i Δ p \qquad ( 10 )$$

In embodiments, Eₚ⁺ is electric field of the right circularly (RC) polarized light and it is responsible of the polarization of the medium which can be expressed as:

$${P}_{1} = χ + {ε}_{0} E {p}^{+} \qquad ( 11 )$$

Similarly, Eₚ⁻ is the electric field of the left circularly (LC) polarized light polarizing the medium to have:

$${P}_{2} = {χ}^{{}_{-}} {ε}_{0} {E}_{{p}^{-}} \qquad ( 12 )$$

In embodiments, P₁=2Nμ_{co}ρ_{ca} and P₂=2Nμ_{dp}ρ_{da}. P represents the induced polarization caused by the interaction of the electric field and the atoms. μca and μda are the dipole matrices elements. Besides, ρ_{ca} (ρ_{da}) are the density matrix elements for the right (left) circularly polarized light, respectively.

In embodiments, the equations for susceptibilities (right and left) χ+ and (χ−) of the medium are be obtained as

$${χ}^{\pm } = \frac{α}{4 π {k}_{p}} {S}^{\pm } \qquad ( 13 )$$

$${S}^{+} = \frac{{ρ}_{c a}}{{Ω}_{p}^{+}} \qquad ( 14 )$$

$${S}^{-} = \frac{{ρ}_{d a}}{{Ω}_{p}^{-}} \qquad ( 15 )$$

In embodiments,

$$α l = \frac{4 π {k}_{p} N {\vert μ \vert}^{2} l}{ℏ {ε}_{o}}$$

where l and kp are the length of the atomic medium and probe field wave number respectively. Moreover, N indicates electron number density in the medium and μ=μ_{da}=μ_{ca} The trapped Rb⁸⁷ atoms typically exhibit a Gaussian density distribution denoted by N (N being the atomic number density of the trapped atoms in the 1D lattice). This is distributed in a Gaussian shape given by:

$${N}_{s} ( y ) = {N}_{O} {e}^{- \frac{( y - {y}_{s} )}{{{σ}^{2}}^{}}} \qquad ( 16 )$$

In embodiments, where

$$y ∈ ( {y}_{s} - \frac{a}{2} , {y}_{s} + \frac{a}{2} ) .$$

Here, σ stands for the width of the Gaussian distribution and a denotes the period of the lattice with the yₛ being the sth center of the 1D atomic lattice. This Gaussian width depends on the trapping depth of the dipole potentials

In embodiments, the average temperature T of trapped atoms via

$$σ = \frac{{λ}_{o}}{\sqrt{\frac{{K}_{B} T}{2 π \sqrt{2 {U}_{o}}}}} .$$

λo is the wavelength of the laser light used to create the optical lattice. K_{B} is the Boltzmann's constant. T is the temperature of the atomic sample trapped in the optical lattice.

In embodiments, Uₒ is the depth of the lattice potential, N is a function of the lattice position y and the control field g_{c} is considered spatially dependent and periodically modulated along the y direction such as:

$${g}_{c} ( y ) = {g}_{c c} + δ {g}_{c y} Sin ( \frac{2 π ( y - {y}_{s} )}{a} ) \qquad ( 17 )$$

Here, δg_{cy} is the amplitude of the sinusoidal modulation of the control field g_{c} (that is smaller than g_{ce}). The control field g_{c} varies spatially along the y direction and it is modulated with a sinusoidal function of the spatial coordinate y that oscillates with the period a and a is the phase shift yₛ. In embodiments, the MOR of the 1D optical lattice can be obtained as:

$${θ}^{M O R} = \frac{2 π}{λ} ( Re \{ {χ}^{{}_{+}} - {χ}^{{}_{-}} \} ) d \qquad ( 18 )$$

In embodiments, θ^{MOR} is the angle of magneto-optical rotation. This represents the rotation of the polarization plane of light as it travels through the medium. λ is the wavelength of the light. The Re(χ+−χ−) represents the difference in the real parts of the electric susceptibility (χ) for right circularly polarized light (χ+) and left circularly polarized light (χ−). d is the distance the light travels through the medium. The normalized transmission profiles of the probe field due to the left and right polarized light T+(T−) are:

$${T}^{-} = \frac{{\vert ( {E}_{p ( o u t )} ) y \vert}^{2}}{{\vert {E}_{p ( i n )} \vert}^{2}} = \frac{1}{4} {\vert exp [ \frac{ια {ls}^{+}}{2} ] - exp [ \frac{ια {ls}^{-}}{2} ] \vert}^{2} \qquad ( 19 )$$

$${T}^{+} = \frac{{\vert ( {E}_{p ( o u t )} ) x \vert}^{2}}{{\vert {E}_{p ( i n )} \vert}^{2}} = \frac{1}{4} {\vert exp [ \frac{ια {ls}^{+}}{2} ] + exp [ \frac{ια {ls}^{-}}{2} ] \vert}^{2} \qquad ( 20 )$$

Here Ep(out) and Ep(in) represent the magnitudes of the output and input electric fields, respectively (they are squared to calculate the intensities of the fields). α and 1 are related to the attenuation and length of the medium, respectively. Through an asymmetric medium, the difference in absorption of left and right circularly polarized light causes birefringence or dichroism. The medium is birefringent (dichroic) due to the difference in the absorption of the left and right circularly polarized light. The case Re[χ+]≈Re[χ−] and Im[χ+]=Im[χ−] is considered when the medium is birefringent. Hence T⁺ and T⁻ can be written as:

$${T}^{-} = \frac{{\vert ( {E}_{p ( o u t )} ) y \vert}^{2}}{{\vert {E}_{p ( i n )} \vert}^{2}} = \frac{{e}^{- ι β l}}{4} {\vert exp [ \frac{ια {lRes}^{{}_{+}}}{2} ] - exp [ \frac{ια {lRes}^{{}_{-}}}{2} ] \vert}^{2} \qquad ( 19 )$$

$${T}^{+} = \frac{{\vert ( {E}_{p ( o u t )} ) x \vert}^{2}}{{\vert {E}_{p ( i n )} \vert}^{2}} = \frac{{e}^{- ι β l}}{4} {\vert exp [ \frac{ια {lRes}^{{}_{+}}}{2} ] + exp [ \frac{ι a l {Res}^{{}_{-}}}{2} ] \vert}^{2} \qquad ( 20 )$$

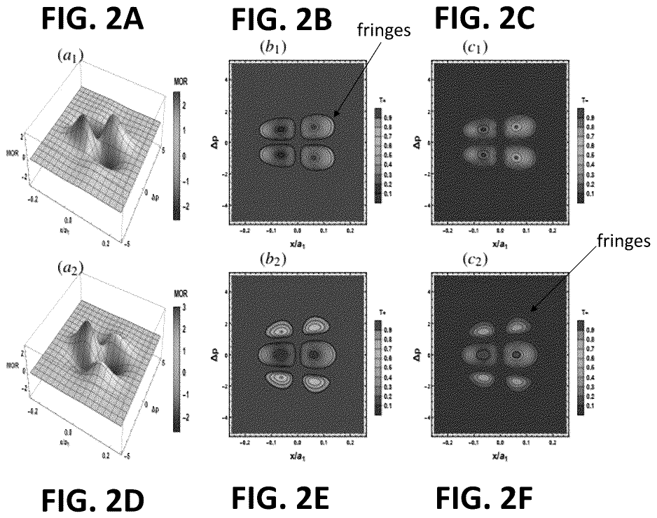

FIGS. 2A, 2B, 2C, 2D, 2E, and 2F show the analysis of the phase effect on the magneto-optical rotation and the transmissions in the 1D lattice along the y-axis at the resonance while the magnetic field effect is very weak (almost 0). In embodiments, this is similar to consider a rotation of the polarization plane of the optical field as it is due to the optical rotation only. This happens hypothetically when the medium molecular structure lacks a plane of symmetry and induces an optical activity only, like in the case of chiral atoms.

Thus, the phase effect is investigated by taking φ=0 for FIGS. 2A, 2B, and 2C, and φ=π/2 in FIGS. 2D, 2E, and 2F. In embodiments, the phase is between the external fields applied in the four level atomic system. In FIG. 2A, two peaks of almost equal are observed at x=−0.15 a, and 0.1 a, for the respective detuning Δp=3.5, and Δp=1. Also, two equal dips are obtained at x=−0.15 a, and x=0.1 a, and for Δp=3.5 and Δp=1. The peaks indicate a positive magneto optical rotation (OR) of 2.5 radians. The dips represent a negative magneto Optical rotation (OR) of −2.5 radian. Over the plane region (the green surface where no dips and no peaks), the left and right susceptibilities of the plan region of FIG. 2A are equal and show no rotation of the polarization plane which is attributed to the isotropy within the medium. From another hand, different orientations with respect to the applied magnetic field can result in different magneto-optical responses as seen in the graph, thus anisotropy is induced and it is responsible for the observed magneto optical rotation of the probe field (the peaks and the dips).

By introducing the phase effect, three different peaks are obtained and three dips for φ=π/2 as depicted in FIG. 2D. These peaks occur respectively at x=−0.15, x=0 and x=0 for Δp=2.5, 0 and 4. The three dips are located respectively at x=−0.1, x=−0.1 and x=0.15 for Δp=0, 2.5 and 4. The highest MOR is around 3 rd for the heighest peak while it is around 1.5 rd for the other two peaks. The negative MOR shown by the dips is around −1.5 rd. The appearance of new peaks and dips is enabled by the light phase thus the phase modulates the magneto optical behavior in the 1D lattice.

In FIGS. 2B and 2C, the transmission of the probe light is investigated through the 1D lattice in terms of the detuning. Hence, the transmissions of the right circularly polarized light and the left circularly polarized light are determined, respectively for a very weak magnetic field (almost zero) and for synchronized external fields (the relative phase is zero). In embodiments, a symmetric absorption/transmission fringes behavior is determined, respectively represented by the space inside the fringes/the space outside the fringes in the figures of T+ and T−.

In embodiments, In the transmission spectrum of T+, new regions of transmissions are generated by considering the external fields to be out of phase (see FIG. 2. b₂ in comparison to b₁). Additionally, the susceptibility induces a symmetric effect as shown in b₁ and c₁ or b₂ and c₂. The transmission spectra confirm that a uniform transmission occurs in all isotropic regions (see the uniformity outside of the fringes). Likewise, the anisotropic behavior seen in the MOR graphs is reflected in the transmission spectra. By changing the phase, the MOR can be modulated, the isotropy/anisotropy and the transmission spectra. In this context, it is worth to mention that, generally optical isolators and magneto-optical modulators are used to control the transmission of light in one direction while blocking it in the other, potentially enabling MOR-based sensor applications.

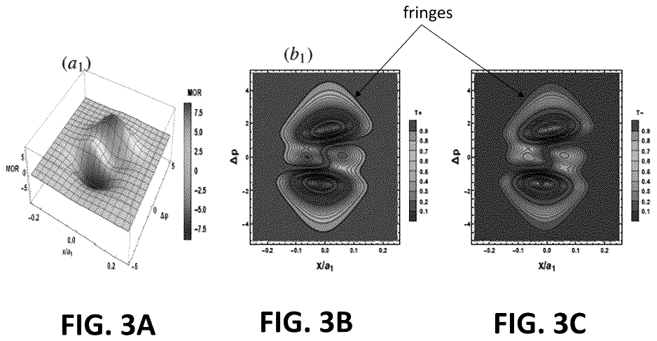

As shown in FIGS. 3A, 3B, and 3C, the magnetic field effect is analyzed on the magneto-optical rotation and the transmissions in the 1D lattice. In the context of our atomic system, FIGS. 3A, 3B, and 3C clearly demonstrate that the external magnetic field affects the rotation of the plane of polarization of light passing through the medium, leading to a distinct change in the MOR.

In embodiments, φ=π/2 and ΔB=0.5 for FIGS. 3A, 3B, and 3C in comparison to FIGS. 2A, 2B, and 2C. In embodiment, the detuning is directly proportional to the magnetic field strength via the relation ℏωB=mₛgₛμ_{B}B where mₛ=±1 is the quantum number (magnetic) of the respective sub-levels of excited states and gₛ is the Lande's factor. As shown in FIG. 3A, one dip at x=−0.05 is occurring at the resonance with a negative magneto optical rotation MOR of ≈−7rd.

By increasing the magnetic field strength to ΔB=0.5 (in comparison FIGS. 2A and/or 2D), the maximum MOR reaches+7.5 rd. Moreover, it is important to note that the structure peaks and dips on the surface undergo significant changes when the magnetic field increases. These changes directly affect the anisotropy of the medium, which is highly linked to the Magneto-Optical Rotation (MOR) effect. In embodiments, the (MOR) is specified by positive or negative values, or peaks/dips. The anisotropy is more accurately described by the direction or axis of alignment of the magnetic moments in a particular direction, rather than being positive or negative. Therefore, in this context, the magnetic field can be used to modulate the anisotropy/isotropy or the magnetic moment alignment in the medium.

Likewise, anisotropic transmission have great applications as they are used to control the transmission of light by manipulating the orientation of magnetic moment alignments. Here, the anisotropy along the 1D lattice enables a tunable transmission via the modulation of the external phase.

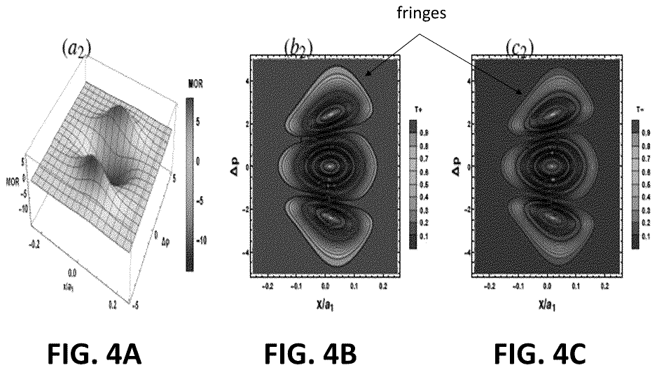

As shown in FIG. 3A, an intermediate peak is located at x=−0.1 and Δp=2.5 with a low MOR value. Far from the resonance the highest peak reaches+7.5 rd at Δp=4.5 and x=−0.1. Thus, the medium shows isotropy in the region of the plane dashed and green whereas the anisotropy is induced by the magnetic field and demonstrated by the peaks, dips presence with an enhanced MOR value. In FIGS. 4A, 4B, and 4C. In embodiments, the effect of the control field on the MOR, transmission and absorption for a weak magnetic field at the resonance while the standing waves are out of phase. As shown in FIG. 4A, the clockwise MOR is dominant (as the dip reaches −13rd), which means that, by increasing the gcc, the dipole moment alignment is manipulated in the |b [symbol] |c [symbol] transition. In FIGS. 4B and 4C, the absorption/transmission is noted around the center of the 1D atomic lattice (in comparison with those shown in other figures).

In embodiments, the red color in the T+ spectrum refers to the total transmission while the colored fringes refer to the partial absorption and transmission. On the other hand, the purple color in FIG. 4C represents the total absorption (See the vertical legend) while the fringes denote the partial absorption/transmission. The behavior of the medium is isotropic beyond the center of the atomic lattice in both FIGS. 4B and 4C.

In FIGS. 2A, 2B, and 2C, identical conditions were analyzed while the control field is weak. Here, it is determined that the transmission and absorption can be centralized around x=0 in the 1D lattice (in contrast to the previous scenario), where transmission and absorption are either expelled from the center or deviated. By varying the strength of the control field, the Lattice can be engineered to exhibit either centralized anisotropy around x=0 or isotropic behavior. This ability to engineer the isotropy or anisotropy behavior allows for selective transmission or absorption of light, which in turn enables tailored filtering of light based on its polarization.

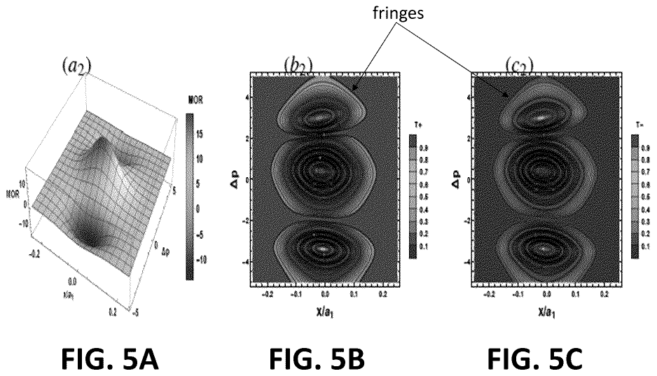

Further increase of the control field strength, induces a giant MOR out of the resonance. As shown in FIG. 5A, the MOR varies between −15 rd and 18 rd. In contrast to the usual case where in the far detuning the MOR is affected, large MOR values are shown. This giant MOR is attributed to the joint conditions used here: gk=3 and ΔB=0.5. Indeed, the magnetic field (proportional to ΔB) can cause changes in the population distribution among the four Levels, altering the atom's absorption or transmission properties and rotating the polarization plane of the transmitted light whereas gk manipulates the excited and ground state.

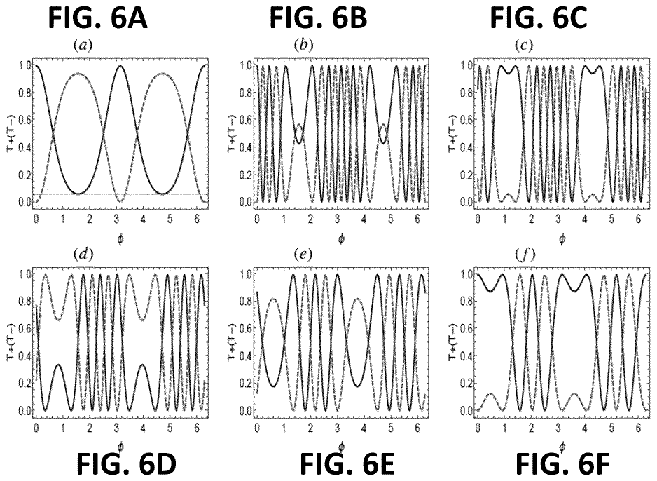

FIGS. 6A, 6B, and 6C show the phase effect on the right and left circularly polarized light. In FIG. 6A both the magnetic field and the control field are weak. Here, w one transmitted peak for the RCL while the absorption profile has two peaks (for the LCL). In fact, for φ is 3.2 rd the LCL is totally absorbed while the RCL is transmitted. Furthermore, for φ is 0,6, 2,4, 3,8 and 5,8 rd that, 50% of the RCL is transmitted (i,e the LCL) while the other 50% is blocked. In FIG. 6B, the control field gkis increased to 4 γ while maintaining a weak magnetic field.

Hence, selective transmission peaks can be generated depending on the external fields phase φ. For instance (see FIG. 6B), two band transmissions are observed between which partial transmissions occur. Multiple transmission peaks occur between φ=2 and φ=2, repetitively similar to the honey comb phenomena. It is noticed that for φ=1.6 and φ=4.8, the light is filtered to a specific value, 55% of the LCL is transmitted while 45% of the RCL is transmitted. Likewise, 45% of the LCL is blocked in contrast of 55% of the RCL. In FIG. 6C, for φ=1.2 and for φ=4.3 only 5% of the LCL is transmitted (95% is blocked) and and 95% of the RCL is transmitted (5% are blocked).

FIGS. 6E, 6F, and 6G, the effect of the magnetic field are observed on the light filtering. In embodiments, the honey comb behavior of the transmission is shifted towards the lower φ (see FIGS. 6C and 6D) For φ=0.4 rd, the LCL in FIG. 6C is totally transmitted while the the RCL is blocked which is kept the same in FIG. 6. (d). However, for φ=0.8 rd, in FIG. 6C, halph halph transmission occurs, blockage respectively for LCL and RCL, this rate changes by increasing the magnetic field.

As shown in FIG. 6D, at φ=0.8 rd, 30% of the RCL is transmitted and 70% is blocked, and vice versa. In d and e, it is clear that the magnetic field induces a selective filtering to the light (see for φ=4 rd). A further increase of the magnetic field (see FIG. 6F) induces an inversion in the light filtering behavior. For instance, at φ=0 1.8 rd the RCL is transmitted while it was blocked in FIG. 6D, a blockage/transmission inversion occurs for the LCL. Thus, due to the polarization-dependent of the MOR, a transmission/absorption occurs with a behavior similar to that induced by the anisotropy effect. This means, that along the 1D lattice directions, regions with higher lattice potential exhibit different absorption/transmission compared to regions with lower lattice potential.

FIG. 7 is a diagram of example environment 700 in which systems, devices, and/or methods described herein may be implemented. FIG. 7 shows network 701, apparatus 700, and database 702. Network 701 may include a local area network (LAN), wide area network (WAN), a metropolitan network (MAN), a telephone network (e.g., the Public Switched Telephone Network (PSTN)), a Wireless Local Area Networking (WLAN), a WiFi, a hotspot, a Light fidelity (LiFi), a Worldwide Interoperability for Microware Access (WiMax), an ad hoc network, an intranet, the Internet, a satellite network, a GPS network, a fiber optic-based network, and/or combination of these or other types of networks.

Additionally, or alternatively, network 701 may include a cellular network, a public land mobile network (PLMN), a second generation (2G) network, a third generation (3G) network, a fourth generation (4G) network, a fifth generation (5G) network, and/or another network. In embodiments, network 722 may allow for devices describe in any of the figures to electronically communicate (e.g., using emails, electronic signals, URL links, web links, electronic bits, fiber optic signals, wireless signals, wired signals, etc.) with each other so as to send and receive various types of electronic communications. In embodiments, network 701 may include a cloud network system that incorporates one or more cloud computing systems.

Apparatus 700 may include any computation or communications device that is capable of communicating with a network (e.g., network 701). Apparatus 700 is described in FIG. 7 and may include additional features described herein. For example, apparatus 700 may include a radiotelephone, a personal communications system (PCS) terminal (e.g., that may combine a cellular radiotelephone with data processing and data communications capabilities), a personal digital assistant (PDA) (e.g., that can include a radiotelephone, a pager, Internet/intranet access, etc.), a smart phone, a desktop computer, a laptop computer, a tablet computer, a camera, a personal gaming system, a television, a set top box, a digital video recorder (DVR), a digital audio recorder (DUR), a digital watch, a digital glass, or another type of computation or communications device.

Apparatus 700 may receive and/or display electronic content. In embodiments, the electronic content may include objects, data, images, audio, video, text, files, and/or links to files accessible via one or more networks. Content may include a media stream, which may refer to a stream of electronic content that includes video content (e.g., a video stream), audio content (e.g., an audio stream), and/or textual content (e.g., a textual stream). In embodiments, an electronic application may use an electronic graphical user interface to display content and/or information via apparatus 700. Apparatus 700 may have a touch screen and/or a keyboard that allows a user to electronically interact with an electronic application or a webpage (either containing electronic content). In embodiments, apparatus 700 may be used to generate one or more graphs and analysis as described in FIGS. 1-6 and 10.

Apparatus 702 may correspond to a magnetic optical trap (MOT) device. In embodiments, the MOT is a combination of laser beams and magnetic fields to trap and cool neutral atoms to extremely low temperatures, such as temperature readings in microkelvins. In embodiments, apparatus 702 may include two lasers that are frequency so that they may detuned to the red of the atomic transitions and stabilized to less than a particular MIz natural transition linewidth level. In embodiments, apparatus 702 can be used to trap atoms and may have features similar to those described in FIG. 9. In embodiments, apparatus 700 may be a part of apparatus 702 or may be separate devices. In embodiments, apparatus 700 may send electronic communications based on the described information relating to FIGS. 1-6 and 10 to control the MOT to generate the trapped atom by adjusting phases, magnetic waves, and other features.

FIG. 8 is a diagram of example components of a device 800. Device 800 may correspond to network 701, apparatus 700, and device 702. Alternatively, or additionally, network 701, apparatus 700, computing system 714, and/or database 702 may include one or more devices 800 and/or one or more components of device 800.

As shown in FIG. 8, device 800 may include a bus 810, a processor 820, a memory 830, an input component 840, an output component 850, and a communications interface 860. In other implementations, device 800 may contain fewer components, additional components, different components, or differently arranged components than depicted in FIG. 8. Additionally, or alternatively, one or more components of device 800 may perform one or more tasks described as being performed by one or more other components of device 800.

Bus 810 may include a path that permits communications among the components of device 800. Processor 820 may include one or more processors, microprocessors, or processing logic (e.g., a field programmable gate array (FPGA) or an application specific integrated circuit (ASIC)) that interprets and executes instructions. Memory 830 may include any type of dynamic storage device that stores information and instructions, for execution by processor 820, and/or any type of non-volatile storage device that stores information for use by processor 820. Input component 840 may include a mechanism that permits a user to input information to device 800, such as a keyboard, a keypad, a button, a switch, voice command, etc. Output component 850 may include a mechanism that outputs information to the user, such as a display, a speaker, one or more light emitting diodes (LEDs), etc.

Communications interface 860 may include any transceiver-like mechanism that enables device 800 to communicate with other devices and/or systems. For example, communications interface 860 may include an Ethernet interface, an optical interface, a coaxial interface, a wireless interface, or the like. In another implementation, communications interface 860 may include, for example, a transmitter that may convert baseband signals from processor 820 to radio frequency (RF) signals and/or a receiver that may convert RF signals to baseband signals. Alternatively, communications interface 960 may include a transceiver to perform functions of both a transmitter and a receiver of wireless communications (e.g., radio frequency, infrared, visual optics, etc.), wired communications (e.g., conductive wire, twisted pair cable, coaxial cable, transmission line, fiber optic cable, waveguide, etc.), or a combination of wireless and wired communications.

Communications interface 860 may connect to an antenna assembly (not shown in FIG. 8) for transmission and/or reception of the RF signals. The antenna assembly may include one or more antennas to transmit and/or receive RF signals over the air. The antenna assembly may, for example, receive RF signals from communications interface 860 and transmit the RF signals over the air, and receive RF signals over the air and provide the RF signals to communications interface 860. In one implementation, for example, communications interface 860 may communicate with network 801.

As will be described in detail below, device 800 may perform certain operations. Device 800 may perform these operations in response to processor 820 executing software instructions (e.g., computer program(s)) contained in a computer-readable medium, such as memory 830, a secondary storage device (e.g., hard disk.), or other forms of RAM or ROM. A computer-readable medium may be defined as a non-transitory memory device. A memory device may include space within a single physical memory device or spread across multiple physical memory devices. The software instructions may be read into memory 830 from another computer-readable medium or from another device. The software instructions contained in memory 830 may cause processor 820 to perform processes described herein. Alternatively, hardwired circuitry may be used in place of or in combination with software instructions to implement processes described herein. Thus, implementations described herein are not limited to any specific combination of hardware circuitry and software.

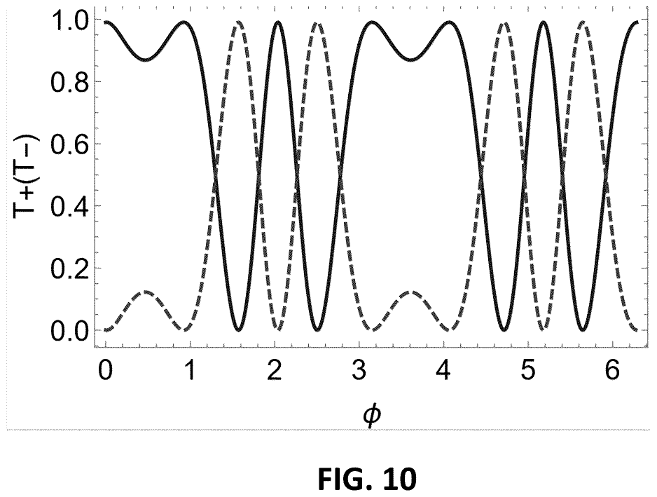

FIG. 10 shows an example graph. In embodiments, once a 1D standing wave is applied to trap an atom, a filter can be generated to filter the light. In embodiments, FIG. 10 shows specific values of the phase used to manipulate the MOR. In embodiments, FIG. 10 shows specific values of the angle phi that can be used either for blocking light or transmission.

The above-described examples may be implemented in many different forms of software, firmware, and hardware in the implementations illustrated in the figures. In embodiments, the actual software code or specialized control hardware used to implement these aspects should not be construed as limiting. Thus, the operation and behavior of the aspects were described without reference to the specific software code—it being understood that software and control hardware could be designed to implement the aspects based on the description herein.

Even though particular combinations of features are recited in the claims and/or disclosed in the specification, these combinations are not intended to limit the disclosure of the possible implementations. In fact, many of these features may be combined in ways not specifically recited in the claims and/or disclosed in the specification. Although each dependent claim listed below may directly depend on only one other claim, the disclosure of the possible implementations includes each dependent claim in combination with every other claim in the claim set.

While various actions are described as selecting, displaying, transferring, sending, receiving, generating, notifying, and storing, it will be understood that these example actions are occurring within an electronic computing and/or electronic networking environment and may require one or more computing devices, as described in FIG. 7, to complete such actions. Also, it will be understood that any of the various actions can result in any type of electronic information to be displayed in real-time and/or simultaneously on multiple devices.

No element, act, or instruction used in the present application should be construed as critical or essential unless explicitly described as such. Also, as used herein, the article “a” is intended to include one or more items and may be used interchangeably with “one or more.” Where only one item is intended, the term “one” or similar language is used. Further, the phrase “based on” is intended to mean “based, at least in part, on” unless explicitly stated otherwise.

In the preceding specification, various preferred embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

What is claimed is:

1. A method, comprising:
manipulating, by a device, a left and right circularly polarized light, wherein left and right susceptibilities are fully controlled,
controlling, by the device, light transmission based on controlling the left and right susceptibilities;
inducing, by the device, an isotropy or anisotropy effect, wherein the isotropy or anisotropy effect is observable in a transmission or absorption spectra;
manipulating, by the device, a phase and magnetic field, wherein the manipulating the phase and magnetic field results in a honey comb behavior; and
determining, by the device, a magneto-optical rotation (MOR) in a one-dimensional (1D) lattice via a four-level atomic system with bi-refringence.

2. The method of claim 1, wherein the determining the MOR includes trapping an atom.

3. The method of claim 1, wherein the magnetic field affects a rotation of a plane of polarization of light.

4. The method of claim 1, wherein the MOR goes up to −13 rd.

5. A device, comprising:
memory, and
a processor to:
manipulate a left and right circularly polarized light, wherein left and right susceptibilities are fully controlled,
control light transmission based on controlling the left and right susceptibilities;
induce an isotropy or anisotropy effect, wherein the isotropy or anisotropy effect is observable in a transmission or absorption spectra;
manipulate a phase and magnetic field, wherein the manipulating the phase and magnetic field results in a honey comb behavior; and
determine a magneto-optical rotation (MOR) in a one-dimensional (ID) lattice via a four-level atomic system with bi-refringence.

6. The device of claim 5, wherein the determining the MOR includes trapping an atom.

7. The device of claim 5, wherein the magnetic field affects a rotation of a plane of polarization of light.
